(19) United States
(12) Patent Application Publication
(10) Pub. No.: US 2025/0172864 A1
(43) Pub. Date: May 29, 2025

(54) REFLECTIVE MASK BLANK AND REFLECTIVE MASK

(71) Applicant: AGC Inc., Tokyo (JP)

(72) Inventor: Takeshi OKATO, Tokyo (JP)

(73) Assignee: AGC Inc., Tokyo (JP)

(21) Appl. No.: 19/026,266

(22) Filed: Jan. 16, 2025

Related U.S. Application Data
(63) Continuation of application No. PCT/JP2023/027272, filed on Jul. 25, 2023.

(30) Foreign Application Priority Data
Aug. 3, 2022 (JP) 2022-124355

(51) Int. Cl. G03F 1/24; G03F 1/26

(52) U.S. Cl. CPC G03F 1/24; G03F 1/26

(57) ABSTRACT

A reflective mask blank 10 for EUV lithography in which a multi-layer reflection film 2 that reflects EUV light and an absorption layer 3 that absorbs EUV light are laminated on a substrate 1 in the stated order from the substrate 1 side, wherein the absorption layer 3 has a refractive index of less than 0.94 and an extinction coefficient of 0.060 or less for EUV light having a wavelength of 13.5 nm, and a phase difference between reflected light from a surface of the multi-layer reflection film and reflected light from a surface of the absorption layer with respect to an incident ray of the EUV light having a wavelength of 13.5 nm is 220 to 320°, and a reflective mask in which a mask pattern is formed on the absorption layer 3.

### CROSS-REFERENCE TO RELATED PATENT APPLICATIONS

This application is a U.S. Bypass Continuation of International Patent Application No. PCT/JP2023/027272, filed on Jul. 25, 2023, which is based upon and claims the benefit to Japanese Patent Application No. 2022-124355, filed on Aug. 3, 2022. The contents of these applications are hereby incorporated by reference in their entireties.

### TECHNICAL FIELD

The present invention relates to a reflective mask blank for use in extreme ultraviolet (EUV) lithography in semiconductor manufacturing and the like, and a reflective mask with the reflective mask blank.

### BACKGROUND ART

In a reflective mask for use in EUV lithography, a mask pattern by an absorption layer that absorbs EUV light is provided on a multi-layer reflection film that reflects short-wavelength EUV light having a wavelength of about 13.5 nm. In the reflective mask, an increased thickness of the absorption layer is likely to cause a dimension error of a transfer pattern due to so-called shadowing in which EUV light entering obliquely (typically at an incidence angle of 6°) and a reflected ray of the light are blocked.

For suppressing a dimension error due to the shadowing, efforts are being made so that the thickness of an absorption layer of a mask is as small as possible. In addition, technical development of phase shift masks is underway to improve the contrast of an edge portion of the transfer pattern by an absorption layer formed so as to absorb EUV light and reflect light such that it differs in phase from reflected light from a multi-layer reflection film.

Meanwhile, a transmissive phase shift mask is such that to a transmission portion of a mask pattern, a substance or shape different in refractive index and transmittance from the transmission portion is added to change the optical phase of the portion, thereby improving the resolution. In a region where the phase is changed, transmission diffraction rays of light having phase difference interfere with each other, leading to a decrease in light intensity. This improves the contrast of the transfer pattern, so that the focal depth during transfer expands, and transfer accuracy is improved.

In a halftone mask which is a type of transmissive phase shift mask, a thin film semitransparent to exposure light is formed at a portion where the phase of transmitted light is changed. The halftone mask can improve transfer accuracy by reducing the transmittance to approximately several percents (typically about 2.5 to 15.0% relative to the substrate transmitted light), and simultaneously changing the phase to improve the resolution of a pattern edge portion.

The best phase difference is 180° in principle, but it is known that in practice, a resolution improving effect can be obtained when the phase difference is about 175 to 185°.

For the reflective mask for EUV lithography, the principle of improving the resolution by the phase shift effect has been considered the same as that for the transmissive mask except that the “transmittance” is replaced by the “reflectance”. That is, it has been considered desirable that the EUV light reflectance of the absorption layer be 2.5 to 15.0%, and the phase difference between a reflected ray of EUV light from the reflection layer and a reflected ray of EUV light from the absorption layer (hereinafter, also referred to simply as “phase difference”) be 175 to 185°.

For this reason, the phase shift mask in a conventional reflective mask is generally designed such that the phase difference is about 180° (corresponding to being substantially reversed) (see, for example, Patent Literature 1).

On the other hand, in the reflective mask, light enters obliquely, unlike the transmissive mask in which light enters perpendicularly, and the optimum phase difference has been recently reported to be 216° (=1.2π).

### CITATION LIST

### Patent Literature

PTL1: JP 2011-29334 A

### SUMMARY OF INVENTION

### Technical Problem

Thus, the absorption layer of the reflective mask has been designed such that on the basis of a refractive index of a constituent material (which may be represented by n hereinafter) and an extinction coefficient (which may be represented by k hereinafter), the thickness of the absorption layer is set so that the phase difference is 180° or 216°, but the optimum values of the reflectance, the phase difference and the thickness of the absorption layer vary depending on exposure conditions, a shape of the transfer pattern and the like, and are difficult to simply define.

Recently, for essential parts of computers and electric equipment, large-scale integrated circuits (LSIs) have been utilized in which a large number of MOS transistors, resistors and capacitors are integrated on one chip. Among LSIs, for example, elements of dynamic random access memories (DRAMs) and the like have become finer at a rapid rate, and accordingly, wiring lines or contact holes for MOS transistors and resistors have been made fine to a level close to the limit of exposure technology. Accordingly, the demand for finer patterns has further increased, and patterning processes have become more complicated.

In fine processing of hole-like patterns, the processing becomes more difficult as the hole width of the hole-like pattern transferred to the element decreases. The numerical aperture (NA) of a lens of an exposure apparatus varies depending on specifications of the EUV exposure apparatus, and the hole width of the transfer pattern which allows processing varies depending on NA. For example, if the hole width of the transfer pattern is 22 nm or less at a NA of 0.33, or the hole width of the transfer pattern is 14 nm or less at a NA of 0.55, it may be difficult to form a transfer pattern with high accuracy even with the phase shift mask described above.

In particular, masks for semiconductor integrated circuits have become complicated with an increase in LSI integration density, and patterns drawn on a mask for use in transfer are required to meet more complicated shapes.

The reflective mask for EUV lithography becomes more susceptible to shadowing as the hole width of the transfer pattern decreases. Therefore, for forming a mask pattern excellent in transfer accuracy, it is required to develop a phase shift mask provided in advance with an absorption layer which ensures that an optimum reflectance and phase difference can be obtained.

The present invention has been made in view of these circumstances, and an object of the present invention is to provide a reflective mask for EUV lithography which can form a transfer pattern with high dimension accuracy with respect to fine hole-like patterns, and a reflective mask blank that is used for the reflective mask.

### Solution to Problem

The present invention is based on the discovery that a transfer pattern can be formed with high dimension accuracy with respect to fine hole-like patterns in EUV lithography when the phase difference between reflected light from a multi-layer reflection film and reflected light from an absorption layer is larger than conventional ones at the absorption layer.

Specifically, the present invention is as follows.

[1] A reflective mask blank for EUV lithography in which a multi-layer reflection film that reflects EUV light and an absorption layer that absorbs EUV light are laminated on a substrate in the stated order from the substrate side, wherein the absorption layer has a refractive index of less than 0.94 and an extinction coefficient of 0.060 or less for EUV light having a wavelength of 13.5 nm, and a phase difference between reflected light from a surface of the multi-layer reflection film and reflected light from a surface of the absorption layer with respect to an incident ray of the EUV light having a wavelength of 13.5 nm is 220 to 320°.

[2] The reflective mask blank according to [1], wherein the phase difference is 220 to 280°.

[3] The reflective mask blank according to [1] or [2], wherein the extinction coefficient is 0.050 or less.

[4] The reflective mask blank according to any one of [1] to [3], wherein the extinction coefficient is more than 0.040 and 0.050 or less.

[5] The reflective mask blank according to any one of [1] to [4], wherein a mask pattern comprising hole-like patterns arranged in a cyclic manner is formed on the absorption layer.

[6] The reflective mask blank according to [5], wherein a hole width of a transfer pattern formed by the hole-like patterns is 22 nm or less when a numerical aperture of a lens of an exposure apparatus is 0.33, and 14 nm or less when the numerical aperture of the lens of the exposure apparatus is 0.55.

[7] The reflective mask blank according to any one of [1] to [6], wherein the absorption layer comprises ruthenium (Ru).

[8] The reflective mask blank according to [7], wherein the absorption layer comprises one or more metal elements selected from the group consisting of tantalum (Ta), tungsten (W), chromium (Cr), molybdenum (Mo), niobium (Nb), osmium (Os), iridium (Ir), rhenium (Re) and rhodium (Rh).

[9] The reflective mask blank according to any one of [1] to [8], wherein the absorption layer is formed by laminating two or more films.

[10] The reflective mask blank according to any one of [1] to [9], wherein the absorption layer has a total thickness of 60 nm or less.

[11] The reflective mask blank according to any one of [1] to [10], comprising, between the multi-layer reflection film and the absorption layer, a protective film for protecting the multi-layer reflection film.

[12] A reflective mask for EUV lithography in which a multi-layer reflection film that reflects EUV light and an absorption layer that absorbs EUV light are laminated on a substrate in the stated order from the substrate side, wherein the absorption layer has a refractive index of less than 0.94 and an extinction coefficient of 0.060 or less for EUV light having a wavelength of 13.5 nm, a phase difference between reflected light from a surface of the multi-layer reflection film and reflected light from a surface of the absorption layer with respect to an incident ray of the EUV light having a wavelength of 13.5 nm is 220 to 320°, and a mask pattern is formed on the absorption layer.

[13] The reflective mask according to [12], wherein the phase difference is 220 to 280°.

[14] The reflective mask according to [12] or [13], wherein the extinction coefficient is 0.050 or less.

[15] The reflective mask according to [13] or [14], wherein the extinction coefficient is more than 0.040 and 0.050 or less.

[16] The reflective mask according to any one of [12] to [15], wherein the mask pattern comprises hole-like patterns arranged in a cyclic manner.

[17] The reflective mask according to [16], wherein a hole width of the hole-like pattern is 22 nm or less when a numerical aperture of a lens of an exposure apparatus is 0.33, and 14 nm or less when the numerical aperture of the lens of the exposure apparatus is 0.55.

[18] The reflective mask according to any one of [12] to [17], comprising, between the multi-layer reflection film and the absorption layer, a protective film for protecting the multi-layer reflection film.

### Advantageous Effects of Invention

According to the present invention, there are provided a reflective mask for EUV lithography which can form a transfer pattern with high dimension accuracy for fine hole-like patterns, and a reflective mask blank that is used for the reflective mask.

### BRIEF DESCRIPTION OF DRAWINGS

FIG. 1 is a schematic sectional view schematically showing a reflective mask blank in an embodiment of the present invention.

FIG. 2 is a schematic sectional view schematically showing a reflective mask blank in another embodiment of the present invention.

FIGS. 3A and 3B shows schematic plan views of hole-like patterns formed on an absorption layer of a reflective mask in an embodiment of the present invention. FIG. 3A shows a staggered layout, and FIG. 3B shows an aligned layout.

FIG. 4 is a schematic sectional view schematically showing a reflective mask in an embodiment of the present invention.

FIG. 5 is a schematic sectional view schematically showing a reflective mask in another embodiment of the present invention.

FIG. 6 is a schematic diagram for illustrating a light intensity distribution in a transfer pattern.

FIG. 7A shows a distribution of values of NILS with respect to a refractive index n and an extinction coefficient k, which is obtained by simulation (CD=22 nm, NA=0.33). FIG. 7B shows a distribution of values of phase difference with respect to a refractive index n and an extinction coefficient k, which is obtained by simulation (CD=22 nm, NA=0.33). FIG. 7C shows a distribution of values of NILS with respect to a refractive index n and an extinction coefficient k, which is obtained by simulation (CD=20 nm, NA=0.33). FIG. 7D shows a distribution of values of phase difference with respect to a refractive index n and an extinction coefficient k, which is obtained by simulation (CD=20 nm, NA=0.33).

FIG. 8 shows a distribution of values of phase difference with respect to a total thickness and NILS, which is obtained by (CD=20 to 26 nm, NA=0.33), in an absorption layer including a first layer: Ta₂O₅ (10 nm) and a second layer: Ru.

### DESCRIPTION OF EMBODIMENTS

First, terms in the present specification will be explained.

The meanings of the terms “on a substrate”, “on a layer” and “on a film” (hereinafter, abbreviated as “on a film or the like”) include not only a state of being in contact with an upper surface of a film or the like, but also an upper side that is not in contact with an upper surface of a film or the like. For example, in the case of “a film B on a film A”, the film A and the film B may be in contact with each other, or another film or the like may be interposed between the film A and the film B. The term “upper” used herein does not necessarily mean a high position in the vertical direction, and indicates a relative positional relationship.

The thickness of a film or the like formed can be measured by a transmission electron microscope or an X-ray reflectance method.

A preferred numerical value range can be set by arbitrarily combining a preferred lower limit value and upper limit value.

### [Reflective Mask Blank]

Hereinafter, an embodiment of the present invention will be described with reference to the drawings.

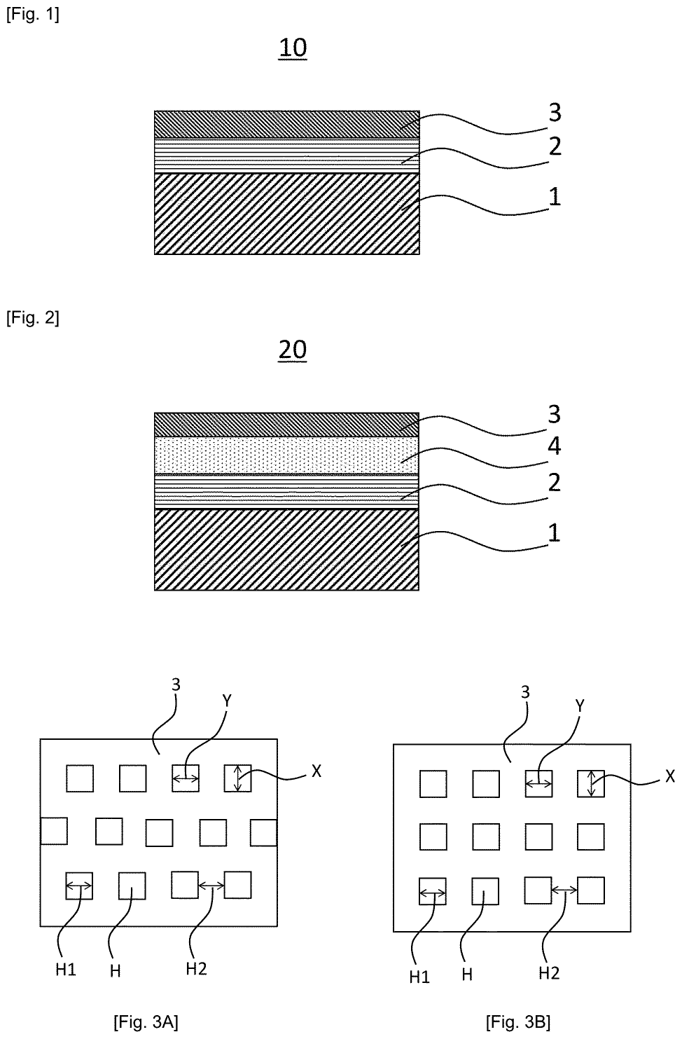

FIGS. 1 and 2 schematically show a cross-section of a reflective mask blank of the present embodiment. In a reflective mask blank 10 shown in FIG. 1, a multi-layer reflection film 2 that reflects EUV light and an absorption layer 3 that absorbs EUV light are laminated on a substrate 1 in the stated order from the substrate 1 side.

As shown in FIG. 2, a protective film 4 (also referred to as a cap layer) for protecting the multi-layer reflection film 2 from dry etching in formation of a mask pattern may be formed between the multi-layer reflection film 2 and absorption layer 3. Further, an antireflection film (not shown) for facilitating pattern defect inspection after mask processing can be formed on the absorption layer 3.

### (Substrate)

From the viewpoint of preventing distortion of a transfer pattern by heat during EUV exposure, the thermal expansion coefficient of the substrate 1 at 20° C. is preferably low, and is preferably 0±0.05×10⁻⁷/° C., and more preferably 0±0.03×10⁻⁷/° C. Preferably, the substrate 1 is excellent in smoothness, has high flatness, and is excellent in resistance to a cleaning liquid used in production processes for reflective masks (chemical resistance).

Examples of the material for the substrate 1 include SiO₂—TiO₂-based glass, and multicomponent glass ceramics. Crystallized glass in which a solid solution of β-quartz is precipitated, quartz glass, silicon, metal and the like can also be used.

From the viewpoint of enabling pattern transfer to be performed with a high reflectance and high accuracy, the substrate 1 is preferably smooth, and has a surface roughness (RMS) of preferably 0.15 nm or less, and more preferably 0.10 nm or less. From the same viewpoint, the flatness (total indicated reading (TIR)) is preferably 100 nm or less, more preferably 50 nm or less, and further more preferably 30 nm or less.

The substrate 1 preferably has high rigidity from the viewpoint of preventing deformation by stress of a film or the like formed on the substrate 1. Specifically, the Young's modulus is preferably 65 GPa or more.

### (Multi-Layer Reflection Film)

From the viewpoint of increasing the EUV light reflectance, the multi-layer reflection film 2 preferably has a configuration in which a plurality of layers whose main components are elements different in refractive index are laminated in a cyclic manner. In general, the multi-layer reflection film 2 has a structure in which a set of one high refractive index layer and one low refractive index layer is defined as one cycle, and laminated about 40 to 60 cycles.

The high refractive index layer/low refractive index layer is generally a Mo/Si multi-layer reflection film, but is not limited thereto, and examples thereof include Ru/Si multi-layer reflection films, Mo/Be multi-layer reflection films, Mo compound/Si compound multi-layer reflection films, Si/Mo/Ru multi-layer reflection films, Si/Mo/Ru/Mo multi-layer reflection films, Mo/Ru/Si multi-layer reflection films, Si/Ru/Mo multi-layer reflection films, and Si/Ru/Mo/Ru multi-layer reflection films.

The reflectance of the multi-layer reflection film 2 for an incident ray of EUV light having a wavelength of about 13.5 nm at an incidence angle of 6° is preferably 60% or more, and more preferably 65% or more.

The thickness of each of films forming the multi-layer reflection film 2 and the repeated cycle of lamination are appropriately set according to film materials and a desired EUV light reflectance.

The multi-layer reflection film 2 can be formed by, for example, depositing the constituent films to a desired thickness using a known deposition method such as a magnetron sputtering method or an ion beam sputtering method.

For example, when a Mo/Si multi-layer reflection film is formed by an ion beam sputtering method, a Si film is first deposited to a thickness of 4.5 nm with a Si target and a Mo film is subsequently deposited to a thickness of 2.3 nm with a Mo target at an ion accelerating voltage of 300 to 1,500 V and a deposition rate of 0.030 to 0.300 nm/sec using argon (Ar) gas (gas pressure 1.3×10⁻² to 2.7×10⁻² Pa) as a sputtering gas. With this as one cycle, a Mo film/Si film is repeatedly laminated 30 to 60 cycles, whereby a Mo/Si multi-layer reflection film can be formed.

### (Protective Film)

The reflective mask blank of the present embodiment may include, between the multi-layer reflection film 2 and the absorption layer 3, a protective film 4 for protecting the multi-layer reflection film 2 from dry etching in formation of a mask pattern. The protective film 4 also has a role of preventing oxidation of the multi-layer reflection film 2 during EUV exposure, which reduces the EUV light reflectance.

The processability of the absorption layer 3 becomes better as the ratio of the rates of etching of the absorption layer 3 and the protective film 4 in the thickness direction with the etching gas in the dry etching (etching rate of absorption layer 3/etching rate of protective film 4) increases. The etching rate ratio is preferably 10 to 200, and more preferably 30 to 100.

As the etching gas, halogen-based gas, oxygen-based gas or a mixture thereof is typically used. Examples of the halogen-based gas include chlorine-based gas containing one or more selected from the group consisting of Cl₂, SiCl₄, CHCl₃, CCl₄ and BCl₃; and fluorine-based gas containing one or more selected from the group consisting of CF₄, CHF₃, SF₆, BF₃ and XeF₂.

Preferably, the protective film 4 contains one or more elements selected from the group consisting of, for example, Ru, Rh and Si. When containing Rh, the protective film 4 may be composed only of Rh, but also preferably contains one or more elements selected from the group consisting of Ru, Nb, Mo, Ta, Ir, Pd, Zr, Y and Ti. Among these elements, one or more selected from the group consisting of Ru, Ta, Ir, Pd and Y are preferable from the viewpoint of improving resistance to the etching gas, and a sulfuric acid/hydrogen peroxide mixture for use in, for example, cleaning of the reflective mask. From the viewpoint of improving the smoothness of the protective film 4, the protective film 4 may contain one or more elements selected from the group consisting of N, O, C and B.

The protective film 4 may be a single-layer film, or may be a multi-layer film including a plurality of layers. When the protective film 4 is a multi-layer film, it can be formed such that the lower layer of the protective film 4 is in contact with the uppermost surface of the multi-layer reflection film 2, and the upper layer of the protective film 4 is in contact with the lowermost surface of the absorption layer 3. By making the protective film 4 have a multi-layered configuration as described above, a material excellent in predetermined function can be used for each layer to make the whole protective film 4 have multiple functions. For example, the protective film 4 may include a layer free of Rh when having a Rh content of 50 at % or more as a whole. When the protective film 4 is a multi-layer film, the thickness of the protective film 4 means a total thickness of the multi-layer film.

The thickness of the protective film 4 is only required to be within a range which allows the above-described role to be sufficiently performed without interfering with the reflection performance of the multi-layer reflection film 2. The thickness of the protective film 4 is preferably 1.0 to 10.0 nm, and more preferably 2.0 to 3.5 nm.

From the same viewpoint, the protective film 4 has a root mean square (RMS) of preferably 0.3 nm or less, and more preferably 0.1 nm or less, and is preferably smooth.

The protective film 4 can be formed by, for example, deposition to a desired thickness using a known deposition method such as a DC sputtering method, a magnetron sputtering method or an ion beam sputtering method.

Further, a buffer layer (not shown) for protecting the multi-layer reflection film 2 during dry etching and defect repairing may be formed between the protective film 4 and the absorption layer 3. Examples of the constituent material of the buffer layer include, but are not limited to, materials containing SiO₂, Cr, Ta or the like as a main component.

### (Absorption Layer)

The absorption layer 3 is formed such that the refractive index is less than 0.94 and the extinction coefficient is 0.060 or less for EUV light having a wavelength of 13.5 nm, and the phase difference between reflected light from the surface of the multi-layer reflection film 2 and reflected light from the surface of the absorption layer 3 with respect to an incident ray of the EUV light having a wavelength of 13.5 nm is 220 to 320°.

The reflective mask blank of the present embodiment, in which the absorption layer 3 has the above-mentioned characteristics, thus is suitable for a reflective mask for EUV lithography which can transfer fine hole-like patterns with high dimension accuracy.

The refractive index of the absorption layer 3 for EUV light having a wavelength of 13.5 nm is less than 0.94, preferably 0.93 or less, and more preferably 0.92 or less. The refractive index is preferably 0.85 or more.

Since the refractive index is within the above-described range, the phase difference between reflected light from the surface of the multi-layer reflection film 2 and reflected light from the surface of the absorption layer 3 is easily increased, and a phase shift mask capable of transferring fine hole-like patterns with high dimension accuracy can be obtained.

The extinction coefficient of the absorption layer 3 for EUV light having a wavelength of 13.5 nm is 0.060 or less, preferably 0.010 to 0.050, more preferably 0.020 to 0.045, and further more preferably 0.030 to 0.040.

Since the extinction coefficient is within the above-described range, a phase shift mask capable of transferring fine hole-like patterns with high dimension accuracy can be obtained.

For sufficiently exhibiting effects as a phase shift mask, the phase difference between reflected light from the surface of the multi-layer reflection film 2 and reflected light from the surface of the absorption layer 3 with respect to an incident ray of EUV light having a wavelength of 13.5 nm is 220 to 320°, preferably 220 to 280°, and more preferably 220 to 260°.

The method for measurement of a phase difference is as described later. The phase difference is a value calculated by optical multi-layer simulation described later.

Since the phase difference is within the above-described range, a phase shift mask capable of transferring fine hole-like patterns with high dimension accuracy can be obtained.

In the present invention, the term “reflected light from the surface of the multi-layer reflection film 2 in the phase shift mask” means that EUV light having a wavelength of 13.5 nm, which has passed through an opening portion of a mask pattern without passing through the absorption layer 3, and directly entered (the protective film 4 and) the multi-layer reflection film 2, is reflected by the multi-layer reflection film 2, and passes through the opening portion of the mask pattern again without passing through the absorption layer 3. The term “reflected light from the surface of the absorption layer 3” means that an incident ray of EUV light having a wavelength of 13.5 nm passes though the absorption layer 3 (and the protective film 4) while being absorbed by the absorption layer 3, is reflected by the multi-layer reflection film 2, and passes through the absorption layer 3 again while being absorbed by the absorption layer 3.

For the absorption layer of the reflective mask for EUV lithography, it is desirable that the thickness be small from the viewpoint of suppressing shadowing as described above, various constituent materials and structures have been under studies, and it has been considered that the best phase difference is 180° or 216°. As the phase difference, a value calculated by optical multi-layer simulation is used in the present invention, but the phase difference can be roughly represented by the following expression (1).

$$θ = 4 π ( \frac{d}{λ} - \frac{d}{λ / n} ) \qquad ( 1 )$$

In expression (1), θ is a phase difference, d is a thickness of the absorption layer 3, λ is a wavelength of incident light, n is a refractive index of the absorption layer 3.

In the present invention, λ=13.5 [nm] and n<1 are met, and thus, an increased refractive index with a decreased thickness leads to a decrease in phase difference of the absorption layer 3.

Examples of the mask pattern formed on the absorption layer 3 of the reflective mask blank 10 include mask patterns including hole-like patterns arranged in a cyclic manner. The mask pattern formed on the absorption layer 3 of the reflective mask blank 10 may have a staggered layout shown in FIG. 3A, or an aligned layout shown in FIG. 3B.

In both the mask patterns shown in FIGS. 3A and 3B, all the widths of the holes H (H1) and the spacings between the holes H (H2) are equal, but there may be a difference between the widths (H1) and between the spacings (H2), or there may be a difference between the width (H1) and the spacing (H2).

In the present specification, the term “hole width” means a major axis of the hole.

EUV lithography is reduced projection exposure. For example, when the numerical aperture (NA) of the lens of the exposure apparatus is 0.33, the scale of the transfer pattern to the mask pattern is 4 times in length (X direction) and 4 times in width (Y direction), and thus, the size of the hole His 4 times the hole width of the transfer pattern in both length (X direction) and width (Y direction). When the numerical aperture (NA) of the lens of the exposure apparatus is 0.55, the scale of the transfer pattern to the mask pattern is 4 times in length (X direction) and 8 times in width (Y direction), and thus, the size of the hole His 4 times the hole width of the transfer pattern in length (X direction) and 8 times the hole width of the transfer pattern in width (Y direction).

The reflective mask blank 10 is suitable when a transfer pattern formed by hole-like patterns includes fine hole-like patterns having a hole width of 22 nm or less in the case where the numerical aperture (NA) of the lens of the exposure apparatus is 0.33, and suitable when the transfer pattern includes fine hole-like patterns having a hole width of 14 nm or less in the case where NA is 0.55, for example.

When the hole width of the transfer pattern is within the above-described range, a further excellent effect as a phase shift mask with high dimension accuracy can be obtained.

The material for forming the absorption layer 3 is not limited as long as it can form a phase shift mask as described above, and examples thereof include materials containing ruthenium (Ru), rhenium (Re), iridium (Ir), osmium (Os), or platinum. In particular, the material for forming the absorption layer 3 preferably contains ruthenium (Ru), and more preferably, further contains one or more metal elements selected from the group consisting of tantalum (Ta), tungsten (W), chromium (Cr), molybdenum (Mo), niobium (Nb), osmium (Os), iridium (Ir), rhenium (Re) and rhodium (Rh). One metal element alone, or two or more metal elements may be contained. When two or more metal elements are contained, the composition ratio of the metals is not limited as long as the refractive index and the extinction coefficient of the absorption layer 3 satisfy the above-described numerical value ranges.

The material may be a single metal element, an alloy, or a compound containing, for example, oxygen (O), nitrogen (N), carbon (C), boron (B) and/or hydrogen (H).

For example, when the constituent material of the absorption layer 3 is a RuTa alloy, the ratio of the Ru content [at %] to the Ta content [at %] (Ru/Ta) is preferably 10 to 97, more preferably 15 to 96, further more preferably 18 to 95.5, and even more preferably 20 to 50. When Ru/Ta is 10 or more, the hydrogen resistance of the phase shift film 13 is easily improved, and when Ru/Ta is 97 or less, the selectivity in etching is high, and the phase shift film 13 is likely to have good processability.

For example, when the constituent material of the absorption layer 3 is a RuCr alloy, the ratio of the Ru content [at %] to the Cr content [at %] (Ru/Cr) is preferably 1 to 13, more preferably 1 to 6, further more preferably 1.5 to 5.7, and even more preferably 1.8 to 5.6. When Ru/Cr is 1 or more, the hydrogen resistance of the phase shift film 13 is easily improved, and when Ru/Cr is 13 or less, the selectivity in etching is high, and the phase shift film 13 is likely to have good processability.

For example, when the constituent material of the absorption layer 3 is a RuW alloy, the ratio of the Ru content [at %] to the W content [at %] (Ru/W) is preferably 1 to 20, more preferably 2 to 18, further more preferably 2 to 15, and even more preferably 2 to 9. When Ru/W is 1 or more, the hydrogen resistance of the phase shift film 13 is easily improved, and when Ru/W is 20 or less, the selectivity in etching is high, and the phase shift film 13 is likely to have good processability.

When the absorption layer 3 contains one or more elements selected from the group consisting of O, N, C, B and H, the total content [at %] of the elements is preferably 1 to 75 at %, more preferably 2 to 72 at %, further more preferably 3 to 50 at %, even more preferably 5 to 30 at %, and particularly preferably 7 to 20 at %.

The absorption layer 3 may have a multi-layered configuration in which two or more films are laminated. It is preferable that the absorption layer 3 has a multi-layered configuration in that predetermined functional layers of different materials can be used as respective layers to design the whole absorption layer 3. Examples of the functional layer include a buffer layer deposited as necessary between the reflection layer and the absorption layer for the purpose of preventing damage given to the reflection layer in patterning, a low-reflection layer formed as necessary on the uppermost layer of the absorption layer 3 for the purpose of improving the contrast during inspection of the mask pattern (a low-reflection layer in a wavelength region of inspection light for the mask pattern), a low-reflection layer formed for the purpose of controlling the reflectance at an EUV wavelength, and a phase control layer deposited for the purpose of controlling the phase at an EUV wavelength.

Examples of the combination of layers in the multi-layered configuration include Ru/Ta₂O₅, Ru/Cr₂O₃, Ir/Ta₂O₅, Ir/Ru, and Pt/Ru. The constituent materials of the layer such as Ru, Ta₂O₅, Cr₂O₃, Ir and Pt may be in the form of an alloy, a nitride, an oxynitride, a boride or the like depending on required characteristics such as optical characteristics, crystallinity, etching properties and durability. The lamination order is not limited. For example, in the case of a two-layered configuration described above, the order of first layer/second layer is preferable.

The refractive index and the extinction coefficient in the case of a multi-layered configuration are determined as a weighted average value of the refractive indexes and extinction coefficients of the layers with each layer thickness taken into account.

The absorption layer 3 can be formed by, for example, depositing the constituent films to a desired thickness using a known deposition method such as a magnetron sputtering method or an ion beam sputtering method.

An absorption layer as described above enables exhibition of an effect as a phase shift mask which can transfer fine hole-like patterns with high dimension accuracy while suppressing shadowing when the total thickness of the absorption layer 3 is 60 nm or less. From the viewpoint of the efficiency of deposition of the absorption layer 3 and etching during formation of the mask pattern, the total thickness of the absorption layer 3 is preferably thin, and preferably 60 nm or less, more preferably 58 nm or less, and further more preferably 53 nm or less. From the viewpoint of the EUV light absorbing effect, the total thickness of the absorption layer 3 is preferably 20 nm or more.

### (Antireflection Film)

When DUV light (deep ultraviolet light) having a wavelength of 190 to 260 nm is used in an inspection process, an antireflection film for preventing reflection (not shown) may be laminated on the absorption layer 3.

The reflective mask may undergo inspection as to whether a mask pattern formed on the absorption layer 3 has defects. In the mask inspection, whether defects are present or not, or the like is determined mainly on the basis of optical data of reflected rays of inspection light, and therefore as the inspection light, light that passes through the mask cannot be used, and DUV light is used. For this reason, when the mask inspection is conducted, it is preferable that an antireflection film for preventing the reflection of DUV light which is inspection light be provided on the absorption layer 3 for the sake of accurate inspection.

For playing the above-described role, the antireflection film is preferably formed of a material having a lower refractive index for DUV light than the absorption layer 3. Examples of the constituent material of the antireflection film include materials containing Ta as a main component, and one or more components selected from the group consisting of Hf, Ge, Si, B, N, H and O in addition to Ta. Specific examples thereof include TaO, TaON, TaONH, TaHfO, TaHfON, TaBSiO, and TaBSiON.

The antireflection film can be formed by, for example, deposition to a desired thickness using a known deposition method such as a magnetron sputtering method or an ion beam sputtering method.

### (Other Configurations)

The reflective mask blank of the present embodiment may be provided with, in addition to the above-described films and layers, functional films known for reflective mask blanks.

For example, for absorptive fixation of the reflective mask blank 10 to, for example, a mount section of an electrostatic chuck, a back electroconductive film may be formed on a surface of the substrate 1 on a side opposite to the multi-layer reflection film 2 (back surface).

The back electroconductive film preferably has a sheet resistance of 100Ω/□ or less, and can be set to a known configuration. Examples of the constituent material of the back electroconductive film include Si, TiN, Mo, Cr, and TaSi. The thickness of the back electroconductive film can be, for example, 10 to 1,000 nm.

The back electroconductive film can be formed by, for example, deposition to a desired thickness using a known deposition method such as a magnetron sputtering method, an ion beam sputtering method, a chemical vapor deposition method (CVD method), a vacuum vapor deposition method or an electroplating method.

The reflective mask blank of the present invention has an EUV light reflectance of preferably 2.0 to 30%, more preferably 3.0 to 25%, further more preferably 5.0 to 20%, even more preferably 6.0 to 15.0%, and particularly preferably 8.0 to 10%.

### [Reflective Mask]

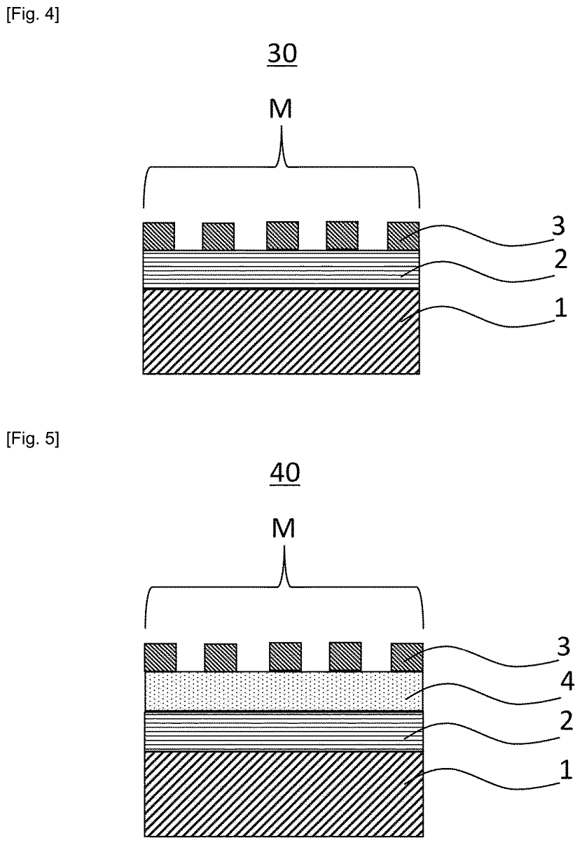

FIGS. 4 and 5 schematically show a cross-section of a reflective mask of the present embodiment. A reflective mask 30 shown in FIG. 4 is a reflective mask for EUV lithography in which the multi-layer reflection film 2 that reflects EUV light and the absorption layer 3 that absorbs EUV light are laminated on the substrate 1 in the stated order from the substrate 1 side, wherein the absorption layer 3 has a refractive index of less than 0.94 and an extinction coefficient of 0.060 or less for EUV light having a wavelength of 13.5 nm, a phase difference between reflected light from a surface of the multi-layer reflection film 2 and reflected light from a surface of the absorption layer 3 is 220 to 320°, and preferably 220 to 280° with respect to an incident ray of the EUV light having a wavelength of 13.5 nm, and a mask pattern M is formed on the absorption layer 3. As shown in FIG. 5, the protective film 4 for protecting the multi-layer reflection film 2 from dry etching in formation of a mask pattern may be formed between the multi-layer reflection film 2 and the absorption layer 3.

The reflective mask of the present invention is such that the mask pattern M is formed on the absorption layer 3 of the reflective mask blank 10 of the present embodiment. Therefore, the descriptions of the layers forming the reflective mask 30 are the same as those for the reflective mask blank 10 above, and are therefore omitted.

The mask pattern M preferably includes hole-like patterns arranged in a cyclic manner from the viewpoint of meeting more complicated semiconductor circuits as described for the reflective mask blank 10 above.

In the reflective mask 30, the normalized image log slope (NILS) of the hole-like patterns is preferably 1.4 or more, more preferably 1.5 or more, and further more preferably 2.0 or more, from the viewpoint of a good contrast of the transfer pattern.

As described for the reflective mask blank 10 above, the reflective mask 30 is suitable when a transfer pattern formed by hole-like patterns includes fine hole-like patterns having a hole width of 22 nm or less in the case where the numerical aperture (NA) of the lens of the exposure apparatus is 0.33, and suitable when the transfer pattern includes fine hole-like patterns having a hole width of 14 nm or less in the case where NA is 0.55, for example.

When the hole width is within the above-described range, a further excellent effect as a phase shift mask with high dimension accuracy can be obtained.

Heretofore, sufficient studies have not been conducted on change of the required characteristics of the absorption layer 3 as the shape of the transfer pattern becomes finer and more complicated. The present invention is based on the discovery that a transfer pattern can be formed with high dimension accuracy when the phase difference between reflected light from a multi-layer reflection film and reflected light from an absorption layer is larger than conventional ones at the absorption layer in a mask including fine hole-like patterns in EUV lithography. The present inventor has given attention to the refractive index n and the extinction coefficient k of the absorption layer 3 for EUV light, and the phase difference, and found that there are ranges which enable achievement of high transfer accuracy in an EUV mask including hole-like patterns.

In the present invention, excellent transfer accuracy of the reflective mask 30 can be presumed by the normalized image log slope (NILS). NILS is a characteristic value representing a contrast of light intensity between a light portion and a dark portion in the transfer pattern. It can be said that the contrast of the transfer pattern increases and transfer accuracy becomes better as the value of NILS becomes higher. NILS is determined by the following expression (2).

$$NILS = CD \times \frac{\partial ln 1 ( x )}{\partial x} \qquad ( 2 )$$

In the expression (2), I(x) represents a light intensity distribution (intensity normalized with the maximum intensity, non-dimensional parameter) in the transfer pattern, x represents a distance (unit: nm) from the position of a peak in a hole width direction of the transfer pattern, and CD represents a critical dimension of the hole width at a resolution limit of the transfer pattern.

In the present specification, CD corresponds to the hole width of the transfer pattern.

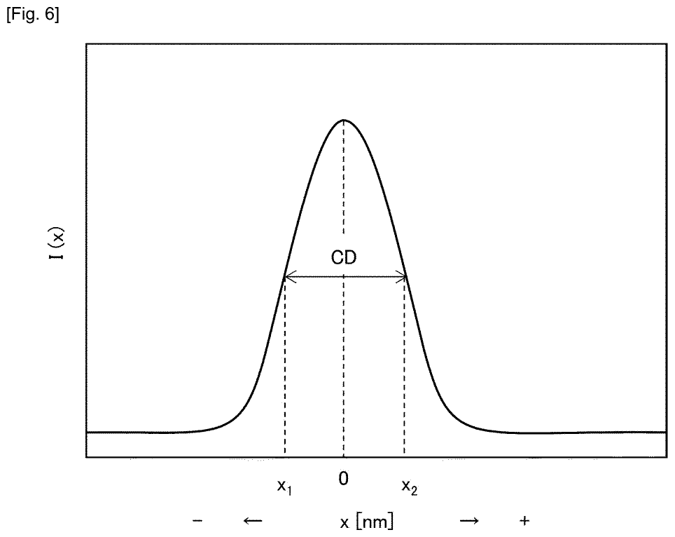

FIG. 6 shows an outline of the light intensity distribution I(x). As shown in FIG. 6, NILS is determined as a product of CD and a slope of ln I(x) (natural logarithm of I(x)) when the width of I(x) in the peak portion (x₂−x₁) is equal to CD. The contrast of the transfer pattern increases as NILS becomes larger.

I(x) is determined by lithography simulation based on a known optical imaging theory (see, for example, Koichi Matsumoto, “Lithography Optics”, “Kogaku”, the Optical Society of Japan, March 2001, Vol. 30, No. 3, p. 40-47). For the simulation, commercially available software (for example, Lithography Simulator “PROLITH” manufactured by KLA-Tencor Corporation); “Sentaurus Lithography” manufactured by Synopsys, Inc.) can also be used.

In the present invention, simulation was performed on the assumption that the numerical aperture NA of the lens of the EUV exposure apparatus is 0.33, or 0.55 with consideration given to a next-generation type for finer patterns.

In the case of NA=0.33, the scale is 4 times in both length and width, and therefore, a mask was assumed in which the size of the hole H of the hole-like patterns is 4 times of CD in both length and width. In the case of NA=0.55, the scale is 4 times and 8 times in length and width, respectively, and therefore, a mask was assumed in which the size of the hole H of the hole-like patterns is 4 times of CD in length and 8 times of CD in width.

For examining an optimum absorption layer at each assumed set value of CD, calculation was repeatedly performed while the refractive index n was changed within the range of 0.88 to 0.96, the extinction coefficient k was changed within the range of 0.015 to 0.065, and the thickness of the absorption layer, d was changed within the range of 20 to 80 nm, and d giving maximum NILS (optimum value) was determined at predetermined n and k. From the values of d, n and k at this time, an optimum value of phase difference was determined.

The setting conditions for the EUV exposure apparatus in simulation are shown below.

### <NA=0.33>

EUV exposure light: λ=13.5 [nm], incidence angle 6°
Opening pattern of phase shift film: hole-like patterns
Scale of transfer pattern: 4 times in length (X direction) and 4 times in width (Y direction)
Critical dimension of hole width of transfer pattern: CD=20 to 26 [nm]
Lighting system: double pole lighting; the optimum values of coherence factors Cout and σᵢₙ at each CD are shown in Table 1.

Table 2 shows the optical simulation results. For the absorption layer 3 shown in Table 2, the optical constants (n, k) of the metal elements are Ru (0.886, 0.017), Ta (0.957, 0.034), Cr (0.932, 0.039) and W (0.933, 0.033), and the compositions of the alloys are Ru_{0.7}Cr_{0.3}, Ru_{0.7}Ta_{0.3} and Ru_{0.5}W_{0.5}. The optical constants of the alloys may slightly vary depending on a density and film formation conditions in a precise sense, and therefore are represented by representative values. The “First layer, Second layer” in Table 2 means that the layers are formed in the stated order from the substrate 1 side.

TABLE 1

| NA | CD[nm] | σₒᵤₜ | σᵢₙ |
|---|---|---|---|
| 0.33 | 26 | 0.4 | 0.1 |
| | 24 | 0.5 | 0.2 |
| | 22 | 0.6 | 0.3 |
| | 21 | 0.6 | 0.3 |
| | 20 | 0.6 | 0.3 |

TABLE 2

| | Absorption layer | | | | | | | | |
|---|---|---|---|---|---|---|---|---|---|
| | First layer | | Second layer | | Total | | | | Phase |
| CD | | Thickness | | Thickness | thickness | Refractive | Extinction | | difference |
| [nm] | Material | [nm] | Material | [nm] | [nm] | index | coefficient | NILS | [°] |
| 20 | RuN | 42 | — | — | 42 | 0.893 | 0.016 | 2.45 | 250 |
| 21 | | 42 | | — | 42 | 0.893 | 0.016 | 3.06 | 250 |
| 22 | | 44 | | — | 44 | 0.893 | 0.016 | 3.19 | 247 |
| 24 | | 34 | | — | 34 | 0.893 | 0.016 | 3.46 | 206 |
| 26 | | 37 | | — | 37 | 0.893 | 0.016 | 4.39 | 208 |
| 20 | RuTa | 52 | — | — | 52 | 0.907 | 0.022 | 2.46 | 255 |
| 21 | | 51 | | — | 51 | 0.907 | 0.022 | 3.08 | 246 |
| 22 | | 45 | | — | 45 | 0.907 | 0.022 | 3.21 | 224 |
| 24 | | 40 | | — | 40 | 0.907 | 0.022 | 3.51 | 212 |
| 26 | | 39 | | — | 39 | 0.907 | 0.022 | 4.33 | 204 |
| 20 | Ta₂O₅ | 10 | Ru | 41 | 51 | 0.900 | 0.019 | 2.45 | 259 |
| 21 | | 10 | | 41 | 51 | 0.900 | 0.019 | 3.08 | 259 |
| 22 | | 10 | | 35 | 45 | 0.901 | 0.019 | 3.20 | 228 |
| 24 | | 10 | | 30 | 40 | 0.903 | 0.019 | 3.51 | 214 |
| 26 | | 10 | | 29 | 39 | 0.904 | 0.020 | 4.37 | 204 |
| 20 | Ru | 31 | Ta₂O₅ | 19 | 50 | 0.912 | 0.021 | 2.45 | 232 |
| 21 | | 30 | | 19 | 49 | 0.913 | 0.021 | 3.09 | 226 |
| 22 | | 29 | | 19 | 48 | 0.913 | 0.021 | 3.21 | 225 |
| 24 | | 24 | | 19 | 43 | 0.916 | 0.021 | 3.52 | 192 |
| 26 | | 23 | | 19 | 42 | 0.917 | 0.021 | 4.33 | 183 |
| 20 | Ru | 33 | Ta₂O₅ | 17 | 50 | 0.909 | 0.020 | 2.45 | 247 |
| 21 | | 30 | | 17 | 47 | 0.911 | 0.020 | 3.08 | 228 |
| 22 | | 30 | | 17 | 47 | 0.911 | 0.020 | 3.21 | 228 |
| 24 | | 28 | | 17 | 45 | 0.912 | 0.021 | 3.51 | 215 |
| 26 | | 27 | | 17 | 44 | 0.913 | 0.021 | 4.31 | 210 |
| 20 | RuCr | 52 | — | — | 52 | 0.900 | 0.024 | 2.46 | 271 |
| 21 | | 40 | | — | 40 | 0.900 | 0.024 | 3.09 | 229 |
| 22 | | 45 | | — | 45 | 0.900 | 0.024 | 3.22 | 238 |
| 24 | | 39 | | — | 39 | 0.900 | 0.024 | 3.52 | 218 |
| 26 | | 38 | | — | 38 | 0.900 | 0.024 | 4.34 | 205 |
| 20 | RuW | 58 | — | — | 58 | 0.910 | 0.025 | 2.45 | 268 |
| 21 | | 46 | | — | 46 | 0.910 | 0.025 | 3.08 | 231 |
| 22 | | 46 | | — | 46 | 0.910 | 0.025 | 3.20 | 231 |
| 24 | | 45 | | — | 45 | 0.910 | 0.025 | 3.51 | 218 |
| 26 | | 45 | | — | 45 | 0.910 | 0.025 | 4.27 | 218 |
| 20 | TaN | 59 | — | — | 59 | 0.948 | 0.033 | 2.28 | 180 |
| 21 | | 59 | | — | 59 | 0.948 | 0.033 | 2.82 | 180 |
| 22 | | 59 | | — | 59 | 0.948 | 0.033 | 2.90 | 180 |
| 24 | | 59 | | — | 59 | 0.948 | 0.033 | 3.19 | 180 |
| 26 | | 59 | | — | 59 | 0.948 | 0.033 | 3.77 | 180 |

As can be seen from Table 2, in the case of TaN which has a refractive index of 0.94 or more, the phase difference between reflected light from the surface of the multi-layer reflection film 2 and reflected light from the surface of the absorption layer 3 is as small as 180° even though the thickness of the absorption layer is increased, and it is difficult to obtain a transfer pattern having a high contrast.

Even when the refractive index is less than 0.94 and the extinction coefficient is 0.060 or less, setting CD of the transfer pattern to 24 nm or 26 nm leads to high NILS and a high contrast of the transfer pattern even though the phase difference between reflected light from the surface of the multi-layer reflection film 2 and reflected light from the surface of the absorption layer 3 is less than 220°. On the other hand, it can be said that when CD is 22 nm or less, the phase difference between reflected light from the surface of the multi-layer reflection film 2 and reflected light from the surface of the absorption layer 3 is 220 to 320°, and a transfer pattern with high dimension accuracy can be obtained even though the total thickness is 60 nm or less.

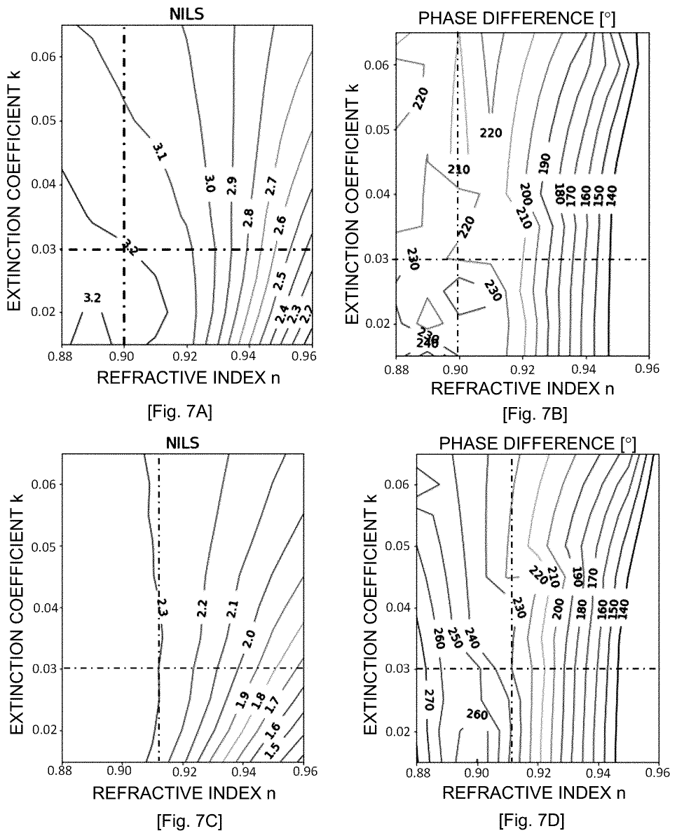

Simulation was performed in which the thickness is changed from 30 nm to 60 nm for each of the refractive index n and the extinction coefficient k of the absorption layer, and the maximum NILS value of hole-like patterns and the corresponding phase difference are represented in the form of contour lines (CD=20 nm, 22 nm, NA=0.33). FIG. 7A shows a distribution of values of NILS with respect to the refractive index n and the extinction coefficient k, which is obtained by simulation (CD=22 nm, NA=0.33), and FIG. 7B shows a distribution of values of phase difference with respect to the refractive index n and the extinction coefficient k, which is obtained by simulation (CD=22 nm, NA=0.33). FIG. 7C shows a distribution of values of NILS with respect to the refractive index n and the extinction coefficient k, which is obtained by simulation (CD=20 nm, NA=0.33), and FIG. 7D shows a distribution of values of phase difference with respect to the refractive index n and the extinction coefficient k, which is obtained by simulation (CD=20 nm, NA=0.33).

In FIGS. 7A and 7B, it can be seen that when CD=22 nm, a region where NILS is high is a region where the refractive index n is low. That is, n is preferably low, and for example, the preferred range is one where n is less than 0.94, more preferably 0.93 or less, and further more preferably 0.92 or less. The extinction coefficient k has less effect as compared to the refractive index n, but it can be seen that NILS is high in a region where k is low. The preferred range is one where k is 0.06 or less, more preferably 0.05 or less, and further more preferably 0.04 or less. The corresponding phase difference can be seen to fall within the range of 220 to 230° although it varies depending on the refractive index n and the extinction coefficient k of the material. Similarly, in FIGS. 7C and 7D, it can be seen that when CD=20 nm, a region where NILS is high is a region where the refractive index n is low. That is, n is preferably low, and for example, the preferred range is one where n is less than 0.94, more preferably 0.93 or less, and further more preferably 0.92 or less. When CD=20 nm, the extinction coefficient k has less effect as compared to the refractive index n, but from the viewpoint of meeting a wide range of CDs, similarly, the preferred range is one where k is 0.06 or less, more preferably 0.05 or less, and further more preferably 0.04 or less. The corresponding phase difference is 230 to 270° although it varies depending on the refractive index n and the extinction coefficient k of the material, and it can be said that the optimum phase difference raises as CD narrows.

The reason why the phase difference at which the value of NILS reaches a maximum raises as CD narrows may be as follows. The phase shift mask makes transmission portions of the mask pattern differ in substance or shape from adjacent transmission portions to give a reversed phase difference to light that has passed through the transmission portions. The photofield continuously changes at interfaces between transmission portions on the mask pattern and adjacent transmission portions. Narrowing of CD leads to a decrease in cycle of irregularities of the EUV mask pattern. Consequently, the photofield inside the structure of the pattern of the EUV mask is largely bent in a shorter cycle as compared to a case where CD is large. That is, if the EUV mask has a structure in which CD is narrower than that sufficiently larger as compared to a wavelength, the contribution of distortion of the field inside the irregularity pattern may increase, resulting in occurrence of a phenomenon in which an average phase difference between a transmission portion of the mask pattern and an adjacent transmission portion becomes smaller than intended (in other words, smaller than a calculated value from the simulation or the expression (1)). Thus, in the case where CD is narrow, the effect of the phase shift mask can be attained by preparing the mask such that the thickness of the mask is adjusted in advance to ensure that a phase difference larger than conventional ones can be given as a phase difference calculated by the simulation or the expression (1).

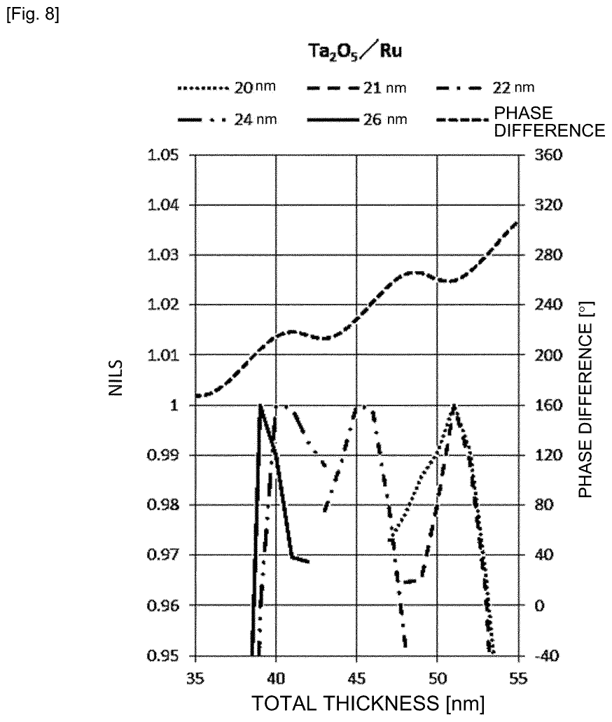

FIG. 8 shows a distribution of values of phase difference with respect to the total thickness and NILS, which is obtained by (CD=20 to 26 nm, NA=0.33) in an absorption layer including a first layer: Ta₂O₅ (10 nm) and a second layer: Ru. From FIG. 8, it can be seen that when CD narrows, the thickness of the absorption layer at which the value of NILS reaches a maximum increases, and the corresponding optimum value of phase difference raises.

The setting conditions for the EUV exposure apparatus in simulation are shown below.

### <NA=0.55>

EUV exposure light: λ=13.5 [nm], incidence angle 5.355°
Opening pattern of phase shift film: hole-like patterns
Scale of transfer pattern: 4 times in length (X direction) and 8 times in width (Y direction)
Critical dimension of hole width of transfer pattern: CD=10 to 18 [nm]
Lighting system: double pole lighting; the optimum values of coherence factors σₒᵤₜ and σᵢₙ at each CD are shown in Table 3.

Table 4 shows the optical simulation results. For the absorption layer 3 shown in Table 4, the optical constants (n, k) of the metal elements are Ru (0.886, 0.017), Ta (0.957, 0.034), Ir (0.905, 0.044) and Os (0.904, 0.043). The compositions of the alloys are Ru_{0.7}Ta_{0.3}, Ru_{0.5}Os_{0.5} and Ru_{0.3}Ir_{0.7}. The optical constants of the alloys are represented by representative values.

TABLE 3

| NA | CD[nm] | σₒᵤₜ | σᵢₙ |
|---|---|---|---|
| 0.55 | 18 | 0.4 | 0.1 |
| | 16 | 0.5 | 0.2 |
| | 14 | 0.5 | 0.2 |
| | 12 | 0.6 | 0.3 |
| | 10 | 0.8 | 0.5 |

TABLE 4

| | Absorption layer | | | | NILS | | | Phase |
|---|---|---|---|---|---|---|---|---|
| CD | | Thickness | Refractive | Extinction | X direction | Y direction | X direction/ | difference |
| [nm] | Material | [nm] | index | coefficient | (4 times) | (8 times) | Y direction | [°] |
| 10 | Ru | 54 | 0.893 | 0.016 | 1.60 | 1.56 | 1.03 | 314 |
| 12 | | 39 | 0.893 | 0.016 | 2.46 | 2.51 | 0.98 | 229 |
| 14 | | 39 | 0.893 | 0.016 | 3.20 | 3.31 | 0.97 | 229 |
| 16 | | 38 | 0.893 | 0.016 | 4.24 | 4.29 | 0.99 | 217 |
| 18 | | 34 | 0.893 | 0.016 | 6.02 | 5.40 | 1.11 | 206 |
| 10 | RuTa | 60 | 0.907 | 0.022 | 1.58 | 1.60 | 0.99 | 298 |
| 12 | | 46 | 0.907 | 0.022 | 2.41 | 2.40 | 1.01 | 236 |
| 14 | | 45 | 0.907 | 0.022 | 3.11 | 3.20 | 0.97 | 224 |
| 16 | | 39 | 0.907 | 0.022 | 4.07 | 4.10 | 0.99 | 204 |
| 18 | | 39 | 0.907 | 0.022 | 6.03 | 5.44 | 1.11 | 204 |
| 10 | Ir | 60 | 0.905 | 0.044 | 1.64 | 1.50 | 1.09 | 301 |
| 12 | | 45 | 0.905 | 0.044 | 2.35 | 2.24 | 1.05 | 227 |
| 14 | | 45 | 0.905 | 0.044 | 2.98 | 2.97 | 1.00 | 227 |
| 16 | | 38 | 0.905 | 0.044 | 3.85 | 3.81 | 1.01 | 199 |
| 18 | | 38 | 0.905 | 0.044 | 5.67 | 5.21 | 1.09 | 199 |
| 10 | RuOs | 60 | 0.895 | 0.030 | 1.63 | 1.53 | 1.06 | 325 |
| 12 | | 39 | 0.895 | 0.030 | 2.41 | 2.36 | 1.02 | 228 |
| 14 | | 39 | 0.895 | 0.030 | 3.09 | 3.12 | 0.99 | 228 |
| 16 | | 38 | 0.895 | 0.030 | 4.05 | 4.05 | 1.00 | 213 |
| 18 | | 38 | 0.895 | 0.030 | 6.03 | 5.67 | 1.07 | 213 |
| 10 | RuIr | 60 | 0.899 | 0.036 | 1.63 | 1.52 | 1.08 | 313 |
| 12 | | 39 | 0.899 | 0.036 | 2.38 | 2.29 | 1.04 | 223 |
| 14 | | 39 | 0.899 | 0.036 | 3.04 | 3.04 | 1.00 | 223 |
| 16 | | 38 | 0.899 | 0.036 | 3.97 | 3.97 | 1.00 | 207 |
| 18 | | 38 | 0.899 | 0.036 | 5.92 | 5.42 | 1.09 | 207 |
| 10 | TaN | 60 | 0.948 | 0.033 | 1.41 | 1.30 | 1.08 | 183 |
| 12 | | 59 | 0.948 | 0.033 | 2.20 | 2.08 | 1.06 | 180 |
| 14 | | 59 | 0.948 | 0.033 | 2.78 | 2.76 | 1.01 | 180 |
| 16 | | 59 | 0.948 | 0.033 | 3.54 | 3.52 | 1.01 | 180 |
| 18 | | 59 | 0.948 | 0.033 | 5.08 | 4.73 | 1.08 | 180 |

Table 4 gives an arrangement based on the thickness at which NILS in the 4 times direction reaches a maximum. The reason why NILS in the 4 times direction is selected as a reference is that the irregularity cycle of the EUV mask pattern becomes smaller as compared to that in the 8 times direction, so that the contribution of distortion of the field inside the irregularity pattern described above increases. In addition, from the viewpoint of mask processing, the irregularity cycle of the EUV mask pattern is smaller and processing is more difficult in the 4 times direction than in the 8 times direction. Therefore, a design to make NILS high in the 4 times direction is desirable from a processing point of view.

As can be seen from Table 4, in the case of TaN which has a refractive index of 0.94 or more, the phase difference between reflected light from the surface of the multi-layer reflection film 2 and reflected light from the surface of the absorption layer 3 is as small as 180 to 183° even though the thickness of the absorption layer is increased, it is difficult to obtain a transfer pattern having a high contrast. Even when the refractive index is less than 0.94 and the extinction coefficient is 0.060 or less, setting CD of the transfer pattern to 16 nm or 18 nm may lead to high NILS and a high contrast of the transfer pattern even though the phase difference between reflected light from the surface of the multi-layer reflection film 2 and reflected light from the surface of the absorption layer 3 is less than 220°. On the other hand, when CD is 14 nm or less, the phase difference between reflected light from the surface of the multi-layer reflection film 2 and reflected light from the surface of the absorption layer 3 is 220 to 320°, and it can be said that a transfer pattern with high dimension accuracy can be obtained even though the total thickness is 60 nm or less.

The reflective mask 30 can be produced by applying a known lithography technique to the reflective mask blank 10 to form the mask pattern M. For example, a photoresist film is formed on the absorption layer 3 of the reflective mask blank 10, and processed to a resist pattern having a desired pattern shape, the absorption layer 3 is etched by dry etching or the like, and an unnecessary photoresist including a resist pattern is then removed, whereby the reflective mask 30 can be obtained in which the mask pattern M is formed on the absorption layer 3. A portion of the absorption layer 3, from which the photoresist has been removed, is a transmission portion, a portion of the absorption layer 3, from which the photoresist has not been removed, is a region between the transmission portions, and the transmission portion and the region form the mask pattern M.

### REFERENCE SIGNS LIST

1 Substrate
2 Multi-layer reflection film
3 Absorption layer
4 Protective film
10, 20 Reflective mask blank
30, 40 Reflective mask
H Hole of hole-like pattern
H1 Width of hole
H2 Spacing between holes
X Length (X direction)
Y Width (Y direction)
M Mask pattern

1. A reflective mask blank for EUV lithography in which a multi-layer reflection film that reflects EUV light and an absorption layer that absorbs EUV light are laminated on a substrate in the stated order from the substrate side,
wherein the absorption layer has a refractive index of less than 0.94 and an extinction coefficient of 0.060 or less for EUV light having a wavelength of 13.5 nm, and
wherein a phase difference between reflected light from a surface of the multi-layer reflection film and reflected light from a surface of the absorption layer with respect to an incident ray of the EUV light having a wavelength of 13.5 nm is 220 to 320°.

2. The reflective mask blank according to claim 1, wherein the phase difference is 220 to 280°.

3. The reflective mask blank according to claim 1, wherein the extinction coefficient is 0.050 or less.

4. The reflective mask blank according to claim 1, wherein the extinction coefficient is more than 0.040 and 0.050 or less.

5. The reflective mask blank according to claim 1, wherein a mask pattern comprising hole-like patterns arranged in a cyclic manner is formed on the absorption layer.

6. The reflective mask blank according to claim 5, wherein a hole width of a transfer pattern formed by the hole-like patterns is 22 nm or less when a numerical aperture of a lens of an exposure apparatus is 0.33, and 14 nm or less when the numerical aperture of the lens of the exposure apparatus is 0.55.

7. The reflective mask blank according to claim 1, wherein the absorption layer comprises ruthenium (Ru).

8. The reflective mask blank according to claim 7, wherein the absorption layer comprises one or more metal elements selected from the group consisting of tantalum (Ta), tungsten (W), chromium (Cr), molybdenum (Mo), niobium (Nb), osmium (Os), iridium (Ir), rhenium (Re) and rhodium (Rh).

9. The reflective mask blank according to claim 1, wherein the absorption layer is formed by laminating two or more films.

10. The reflective mask blank according to claim 1, wherein the absorption layer has a total thickness of 60 nm or less.

11. The reflective mask blank according to claim 1, comprising, between the multi-layer reflection film and the absorption layer, a protective film for protecting the multi-layer reflection film.

12. A reflective mask for EUV lithography in which a multi-layer reflection film that reflects EUV light and an absorption layer that absorbs EUV light are laminated on a substrate in the stated order from the substrate side,
wherein the absorption layer has a refractive index of less than 0.94 and an extinction coefficient of 0.060 or less for EUV light having a wavelength of 13.5 nm,
wherein a phase difference between reflected light from a surface of the multi-layer reflection film and reflected light from a surface of the absorption layer with respect to an incident ray of the EUV light having a wavelength of 13.5 nm is 220 to 320°, and
wherein a mask pattern is formed on the absorption layer.

13. The reflective mask according to claim 12, wherein the phase difference is 220 to 280°.

14. The reflective mask according to claim 12, wherein the extinction coefficient is 0.050 or less.

15. The reflective mask according to claim 12, wherein the extinction coefficient is more than 0.040 and 0.050 or less.

16. The reflective mask according to claim 12, wherein the mask pattern comprises hole-like patterns arranged in a cyclic manner.

17. The reflective mask according to claim 16, wherein a hole width of the hole-like pattern is 22 nm or less when a numerical aperture of a lens of an exposure apparatus is 0.33, and 14 nm or less when the numerical aperture of the lens of the exposure apparatus is 0.55.

18. The reflective mask according to claim 12, comprising, between the multi-layer reflection film and the absorption layer, a protective film for protecting the multi-layer reflection film.
